(19) United States
(12) Patent Application Publication
(10) Pub. No.: US 2012/0201264 A1
(43) Pub. Date: Aug. 9, 2012

(54) LIGHT EMITTING DEVICE WITH VARYING BARRIERS

(76) Inventors: Maxim S. Shatalov, Columbia, SC (US); Alexander Dobrinsky, Providence, RI (US); Michael Shur, Latham, NY (US); Remigijus Gaska, Columbia, SC (US)

(21) Appl. No.: 13/314,545

(22) Filed: Dec. 8, 2011

Related U.S. Application Data
(60) Provisional application No. 61/421,197, filed on Dec. 8, 2010.

(51) Int. Cl. H01S 5/34; H01L 33/06

(52) U.S. Cl. 372/45.01; 257/13; 438/47; 257/E33.008

(57) ABSTRACT

An emitting device including an active region having quantum wells alternating with barriers of varying compositions is provided. The barriers can be composed of a group III-nitride based material, in which a molar fraction of one or more of the group III elements in two barriers adjacent to a single quantum well differ by at least one percent. Two barriers adjacent to a single quantum well can have barrier heights differing by at least one percent.

### REFERENCE TO RELATED APPLICATIONS

The current application claims the benefit of co-pending U.S. Provisional Application No. 61/421,197, titled “Light Emitting Diodes with Graded Barrier,” which was filed on 8 Dec. 2010, and which is hereby incorporated by reference.

### GOVERNMENT LICENSE RIGHTS

This invention was made with government support under contract no. W911NF-10-2-0023 awarded by the Defense Advanced Research Projects Agency (DARPA). The government has certain rights in the invention.

### TECHNICAL FIELD

The disclosure relates generally to emitting devices, and more particularly, to an emitting device having an active region with varying barrier layers, which can improve the light output of the active region.

### BACKGROUND ART

Semiconductor emitting devices, such as light emitting diodes (LEDs) and laser diodes (LDs), include solid state emitting devices composed of group III-V semiconductors. A subset of group III-V semiconductors includes group III-Nitride alloys, which can include binary, ternary and quaternary alloys of indium (In), aluminum (Al), gallium (Ga), and nitrogen (N). Illustrative group III-Nitride based LEDs and LDs can be of the form In_{y}AlₓGa_{1-x-y}N, where x and y indicate molar fraction of a given element, 0≦x, y≦1, and 0≦x+y≦1. Other illustrative group III-Nitride based LEDs and LDs are based on boron (B) nitride (BN) and can be of the form Ga_{z}In_{y}AlₓB_{1-x-y-z}N, where 0≦x, y, z≦1, and 0≦x+y+z≦1.

An LED is typically composed of layers. Each layer has a particular combination of molar fractions for the various elements (e.g., given values of x, y, and/or z). An interface between two layers is defined as a semiconductor heterojunction. At an interface, the combination of molar fractions is assumed to change by a discrete amount. A layer in which the combination of molar fractions changes continuously is said to be graded.

Changes in molar fractions of semiconductor alloys allows for band gap control and are used to form barrier and quantum well (QW) layers. A quantum well comprises a semiconducting layer located between two other semiconducting layers, each of which has a larger band gap than the band gap of the quantum well. A difference between a conduction band energy level of a quantum well and a conduction band energy level of the neighboring semiconductor layers is referred to as a depth of a quantum well. In general, the depth of a quantum well can differ for each side of the quantum well. A barrier comprises a semiconductor layer located between two other semiconductor layers, each of which has a smaller band gap than the band gap of the barrier. A difference between a conduction band energy level of a barrier and a conduction band energy level of a neighboring semiconductor layer is referred to as barrier height. In general, the barrier height of a barrier can differ for each side of the barrier.

A stack of semiconductor layers can include several n-type doped layers and one or more p-type doped layers. An active region of an LED is formed in proximity of a p-n junction where electron and hole carriers recombine and emit light. The active region typically includes quantum wells and barriers for carrier localization and improved radiative recombination. Inside a quantum well, electrons and holes are described quantum mechanically in terms of wave functions. Each wave function is associated with a local energy level inside a given quantum well. An overlap of electron and hole wave functions leads to radiative recombination and light production.

A group III-nitride LED is typically grown as a wurtzite or zinc blende crystal structure. At a heterojunction, the lattice mismatch of the two semiconductor layers causes stresses and strains of the crystal layers and leads to the development of a built-in electric field. In addition, a wurtzite crystal structure exhibits internal electric fields due to spontaneous polarization. The internal electric fields can lead to reduced overlap of electron and hole wave functions and, as a consequence, to reduced light emission.

### SUMMARY OF THE INVENTION

Aspects of the invention provide an emitting device including an active region having quantum wells alternating with barriers of varying compositions. The barriers can be composed of a group III-nitride based material, in which a molar fraction of one or more of the group III elements in two barriers adjacent to a single quantum well differ by at least one percent. Two barriers adjacent to a single quantum well can have barrier heights differing by at least one percent.

A first aspect of the invention provides an emitting device comprising: a group III-nitride based semiconductor structure including an active region, the active region comprising: a plurality of quantum wells; and a plurality of barriers alternating with the plurality of quantum wells, wherein at least one quantum well includes first and second adjacent barriers composed of a group III nitride material, wherein a molar fraction of a group III element in the group III nitride material differs for the first and second adjacent barriers by at least one percent.

A second aspect of the invention provides an emitting device comprising: a group III-nitride based semiconductor structure including an active region, the active region comprising: a plurality of quantum wells; and a plurality of barriers alternating with the plurality of quantum wells, each of the plurality of barriers having a corresponding barrier height, wherein at least one quantum well includes two adjacent barriers having barrier heights differing by at least one percent.

A third aspect of the invention provides a method of manufacturing an emitting device comprising: forming a group III-nitride based semiconductor structure, the forming including: forming an active region in the semiconductor structure, the active region comprising a plurality of quantum wells and a plurality of barriers alternating with the plurality of quantum wells, wherein the active region forming includes: forming a first barrier adjacent to a quantum well, the first barrier having a first molar fraction of a group III element; and forming a second barrier adjacent to the quantum well, the second barrier having a second molar fraction of the group III element, wherein the first and second molar fractions differ by at least one percent.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1 shows a schematic structure of an illustrative emitting device according to an embodiment.

FIG. 2 shows an illustrative active region according to an embodiment.

FIG. 3 shows an illustrative molar fraction histogram for an element in the barriers within the active region of FIG. 2 according to an embodiment.

FIG. 4 shows an illustrative band gap diagram according to the prior art.

FIG. 5 shows an illustrative band gap diagram according to an embodiment.

FIG. 6 shows an illustrative graph of the wall plug efficiencies for various barrier structure configurations according to an embodiment.

FIG. 7 shows an illustrative flow diagram for fabricating a circuit according to an embodiment.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide an emitting device including an active region having quantum wells alternating with barriers of varying compositions. The barriers can be composed of a group III-nitride based material, in which a molar fraction of one or more of the group III elements in two barriers adjacent to a single quantum well differ by at least one percent. Two barriers adjacent to a single quantum well can have barrier heights differing by at least one percent. The varying barrier compositions, grading of individual barriers, and/or modulation of barrier heights can be configured to increase the light output of the active region over that provided by barriers having substantially constant material compositions. As used herein, unless otherwise noted, the term “set” means one or more (i.e., at least one) and the phrase “any solution” means any now known or later developed solution.

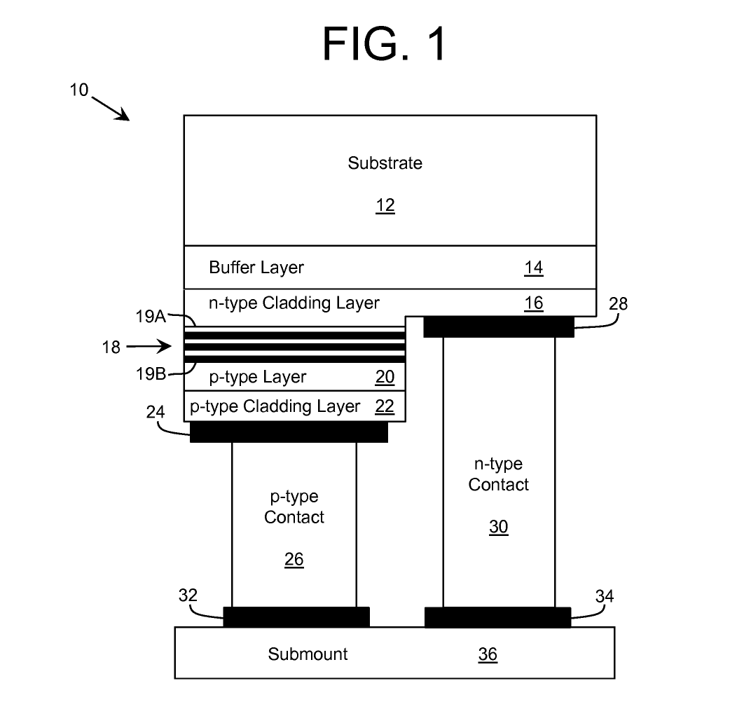

Turning to the drawings, FIG. 1 shows a schematic structure of an illustrative emitting device 10 according to an embodiment. In an embodiment, emitting device 10 is configured to operate as a light emitting diode (LED). Alternatively, emitting device 10 can be configured to operate as a laser diode (LD). In either case, during operation of emitting device 10, application of a bias comparable to the band gap results in the emission of electromagnetic radiation from an active region 18 of the emitting device 10. The electromagnetic radiation emitted by emitting device 10 can comprise a peak wavelength within any range of wavelengths, including visible light, ultraviolet radiation, deep ultraviolet radiation, infrared light, and/or the like.

Emitting device 10 includes a substrate 12, a buffer layer 14 adjacent to the substrate 12, an n-type cladding layer 16 adjacent to the buffer layer 14, and an active region 18 having an n-type side 19A adjacent to the n-type cladding layer 16. Furthermore, emitting device 10 includes a p-type layer 20 adjacent to a p-type side 19B of the active region 18 and a p-type cladding layer 22 adjacent to the p-type layer 20. It is understood that the layer configuration of emitting device 10 is only illustrative. To this extent, emitting device 10 can include an alternative layer configuration, one or more additional layers, and/or the like. As a result, while the various layers are shown immediately adjacent to one another (e.g., contacting one another), it is understood that one or more intermediate layers can be present in an emitting device 10. For example, an illustrative emitting device 10 can include an undoped layer between the active region 18 and one or both of the n-type cladding layer 16 and the p-type layer 20.

In a more particular illustrative embodiment, the emitting device 10 is a group III-V materials based device, in which some or all of the various layers are formed of elements selected from the group III-V materials system. In a still more particular illustrative embodiment, the various layers of the emitting device 10 are formed of group III nitride based materials. Group III nitride materials comprise one or more group III elements (e.g., boron (B), aluminum (Al), gallium (Ga), and indium (In)) and nitrogen (N), such that B_{W}Al_{X}Ga_{Y}In_{Z}N, where 0≦W, X, Y, Z≦1, and W+X+Y+Z=1. Illustrative group III nitride materials include AlN, GaN, InN, BN, AlGaN, AlInN, AIBN, AlGaInN, AlGaBN, AlInBN, and AlGaInBN with any molar fraction of group III elements.

An illustrative embodiment of a group III nitride based emitting device 10 includes an active region 18 composed of In_{y}AlₓGa_{1-x-y}N, Ga_{z}In_{y}AlₓB_{1-x-y-z}N, an AlₓGa₁₋ₓN semiconductor alloy, or the like. Similarly, both the n-type cladding layer 16 and the p-type layer 20 can be composed of an In_{y}AlₓGa_{1-x-y}N alloy, a Ga_{z}In_{y}AlₓB_{1-x-y-z}N alloy, or the like. The molar fractions given by x, y, and z can vary between the various layers 16, 18, and 20. The substrate 12 can be sapphire, or another suitable material, and the buffer layer 14 can be composed of AlN, an AlGaN/AlN superlattice, and/or the like.

As shown with respect to the emitting device 10, a p-type metal 24 can be attached to the p-type cladding layer 22 and a p-type contact 26 can be attached to the p-type metal 24. Similarly, an n-type metal 28 can be attached to the n-type cladding layer 16 and an n-type contact 30 can be attached to the n-type metal 28. The p-type metal 24 and the n-type metal 28 can form ohmic contacts to the corresponding layers 22, 16, respectively. In an embodiment, p-type metal 24 and n-type metal 28 each comprise several conductive and reflective metal layers, while the n-type contact 30 and p-type contact 26 each comprise highly conductive metal. In an embodiment, the p-type cladding layer 22 and/or p-type contact 26 can be at least partially transparent (e.g., semi-transparent or transparent) to the electromagnetic radiation generated by the active region 18. For example, p-type cladding layer 22 and/or p-type contact 26 can comprise a short period superlattice lattice structure, such as an at least partially transparent magnesium (Mg)-doped AlGaN/AlGaN short period superlattice structure (SPSL). Furthermore, the p-type contact 26 and/or the n-type contact 30 can be at least partially reflective of the electromagnetic radiation generated by the active region 18. In another embodiment, the n-type cladding layer 16 and/or n-type contact 30 can be formed of a short period superlattice, such as an AlGaN SPSL, which is at least partially transparent to the electromagnetic radiation generated by the active region 18.

As used herein, a layer is at least partially transparent when the layer allows at least a portion of electromagnetic radiation in a corresponding range of radiation wavelengths to pass there through. For example, a layer can be configured to be at least partially transparent to a range of radiation wavelengths corresponding to a peak emission wavelength for the light (such as ultraviolet light or deep ultraviolet light) emitted by a light generating structure described herein (e.g., peak emission wavelength+/−five nanometers). As used herein, a layer is at least partially transparent to radiation if it allows more than approximately 0.5 percent of the radiation to pass there through. In a more particular embodiment, an at least partially transparent layer is configured to allow more than approximately five percent of the radiation to pass there through. Similarly, a layer is at least partially reflective when the layer reflects at least a portion of the relevant electromagnetic radiation (e.g., light having wavelengths close to the peak emission of the light generating structure). In an embodiment, an at least partially reflective layer is configured to reflect at least approximately five percent of the radiation.

As further shown with respect to the emitting device 10, the device 10 can be mounted to a submount 36 via contacts 26, 30. In this case, the substrate 12 is located on the top of the device 10. To this extent, the p-type contact 26 and the n-type contact 30 can both be attached to a submount 36 via contact pads 32, 34, respectively. The submount 36 can be formed of aluminum nitride (AlN), silicon carbide (SiC), and/or the like.

Any of the various layers of emitting device 10 can comprise a substantially uniform composition or a graded composition. For example, a layer can comprise a graded composition at a heterointerface with another layer. In an embodiment, the p-type layer 20 comprises a p-type blocking layer having a graded composition. The graded composition(s) can be included to, for example, reduce stress, improve carrier injection, and/or the like. Similarly, a layer can comprise a superlattice including a plurality of periods, which can be configured to reduce stress, and/or the like. In this case, the composition and/or width of each period can vary periodically or aperiodically from period to period.

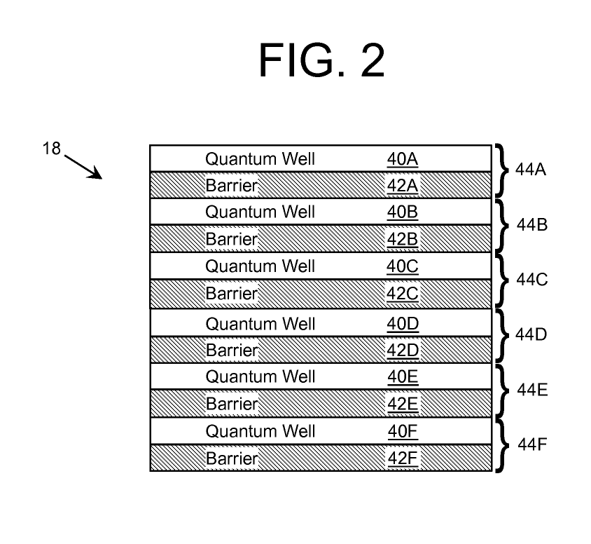

The active region 18 of the emitting device 10 can be formed of a plurality of quantum wells and barriers alternating with the quantum wells. FIG. 2 shows an illustrative active region 18 according to an embodiment. As illustrated, the active region 18 includes a stack of alternating quantum wells 40A-40F and barriers 42A-42F. To this extent, the active region 18 can include a plurality of stacked quantum well/barrier pairs 44A-44F, each of which includes a quantum well and an adjoining barrier. While active region 18 is shown including six pairs 44A-44F, it is understood that an active region 18 can include more or fewer quantum wells 40A-40F and/or barriers 42A-42F. In a typical embodiment, each quantum well 40A-40F can have a thickness of approximately a few nanometers, while the barriers 42A-42F are typically (but not always) wider, and can have a thickness of approximately ten nanometers or more.

As described herein, the barriers 42A-42F of an active region 18 can be composed of a material having molar fractions for one or more of the corresponding elements, which varies between each of the barriers 42A-42F. For example, the barriers 42A-42F can be composed of a Ga_{z}In_{y}AlₓB_{1-x-y-z}N material where one or more of the molar fractions of Al, Ga, In, and/or B varies between the barriers 42A-42F. In an embodiment, at least one pair of barriers adjoining a particular quantum well in the active region 18 are composed of a material where at least one molar fraction of an element in the material of the barriers, such as a group III element in a group III nitride material, differs by at least one percent. Using barriers 42A, 42B, which both adjoin quantum well 40B, as an illustrative example, each barrier can be composed of a Ga_{z}In_{y}AlₓB_{1-x-y-z}N material. However, the molar fraction of at least one of Al, Ga, In, and/or B can differ by at least one percent between the barriers 42A, 42B.

The different compositions of the material for the barriers 42A-42F can be selected to improve light generation in the active region 18 as compared to that provided when all of the barriers 42A-42F include a substantially constant composition of the material. In an embodiment, the barriers 42A-42F are configured to provide a more uniform distribution of carriers (electrons and holes) among the quantum wells 40A-40F as compared to that provided when all of the barriers 42A-42F include a substantially constant composition of the material. In another embodiment, the different compositions of the material for the barriers 42A-42F are configured to provide optimal carrier capture.

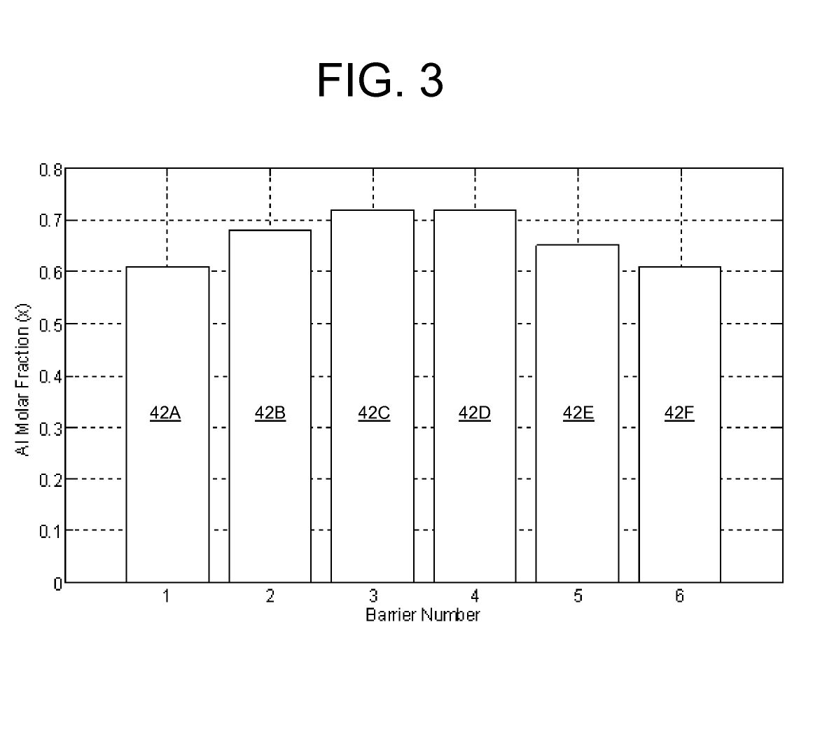

In an illustrative implementation, a barrier height is gradually increased/decreased as the barriers 42A-42F go from barriers located closer to the outer portions of the active region 18, e.g., barriers 42A, 42F, to the barriers located in a central portion of the active region 18, e.g., barriers 42C, 42D. Variation in the barrier heights can be controlled, for example, by varying the molar fractions of an element, such as a group III element, included in the barriers 42A-42F. For example, FIG. 3 shows an illustrative molar fraction histogram for an element in the barriers 42A-42F within the active region 18 (FIG. 2) according to an embodiment. In this case, the barriers 42A-42F can be made of AlGaN with compositions in which the molar fraction of Al varies between the barriers 42A-42F. As illustrated, the barriers 42C, 42D in the central portion of the active region 18 have the highest molar fractions of Al, with the barriers 42B, 42E having lower molar fractions of Al, and the barriers 42A, 42F having the lowest molar fractions of Al.

In FIG. 3, adjacent barriers have Al molar fractions that vary from one another by between approximately 5-11%, although any variation greater than approximately 1% can be utilized and can be selected according to a particular device structure, design requirements, and/or the like. In an embodiment, a difference in barrier height between adjacent barriers is configured to be higher than thermal energy and no larger than two thirds of a conduction band discontinuity between the corresponding quantum well located there between and the highest adjacent barrier. In an embodiment, the Al molar fractions of the outermost barriers 42A, 42F are approximately 40% higher than the Al molar fractions of the quantum wells, whereas the Al molar fractions of the central barriers 42C, 42D are approximately 67% higher than the molar fractions of the quantum wells.

The variation of the molar concentration of an element in the barriers 42A-42F can be configured to increase a barrier height of the barriers 42A-42F as the barriers 42A-42F go from barriers located closer to the outer portions of the active region 18, e.g., barriers 42A, 42F, to the barriers located in a central portion of the active region 18, e.g., barriers 42C, 42D. In an embodiment, a conduction band energy discontinuity and a valance band discontinuity at each of a plurality of heterointerfaces between a barrier layer 42A-42F and a quantum well 40A-40F in the active region 18 is configured to be greater than twice an energy of a longitudinal optical phonon within a material of the active region 18.

It is understood that alternative configurations of variations in the barrier heights of the barriers 42A-42F can be implemented. For example, the barrier heights of the barriers 42A-42F can be configured to increase in a direction from an n-type side of the active region to a p-type side of the active region, increase in a direction from a p-type side of the active region to an n-type side of the active region, decrease from the outer regions of the active region 18 to a central region of the active region 18, and/or the like. A target variation in composition and heights of the barriers 42A-42F can be selected based on, for example, a non-uniformity of the injection of electrons and holes into the active region 18. Furthermore, it is understood that, depending on the element selected, a change in the molar concentration of the element in a barrier can have an inverse or direct relationship to a corresponding change in the barrier height of the barrier. In any event, average barrier heights of each of the barriers 42A-42F can be configured to differ from adjacent barrier(s) 42A-42F by at least one percent.

Additionally, one or more of the barriers 42A-42F can comprise a graded composition, in which the molar concentration of an element in the barrier varies within the barrier. The variation in the graded composition can be selected such that a barrier height of the corresponding barrier increases or decreases in a direction from an n-type side 19A (FIG. 1) of the active region 18 to a p-type side 19B (FIG. 1) of the active region 18. In an embodiment, the barrier height of the barrier is configured to vary similar to that of the varying heights of the adjacent barrier(s). For example, for barriers having the barrier heights shown in FIG. 3, the barrier height of the barriers can be configured such that the barrier height on the side of the barrier closer to the central region of the active region 18 is higher than the barrier height on the side of the barrier closer to the outer region of the active region 18.

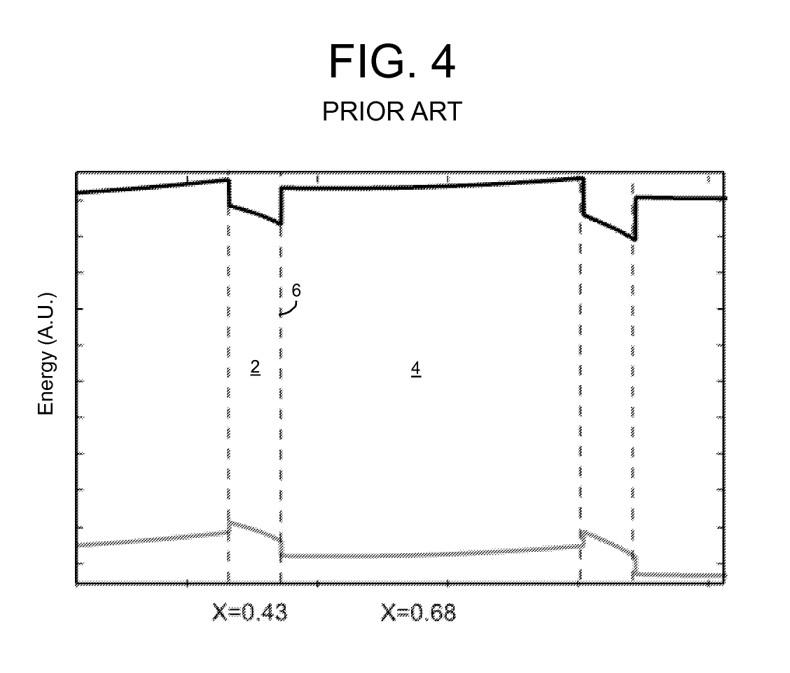

FIG. 4 shows an illustrative band gap diagram according to the prior art. In particular, the band gap diagram corresponds to a portion of an active region having a quantum well 2 and a barrier 4 forming a heterojunction 6 there between for a typical deep ultraviolet LED.

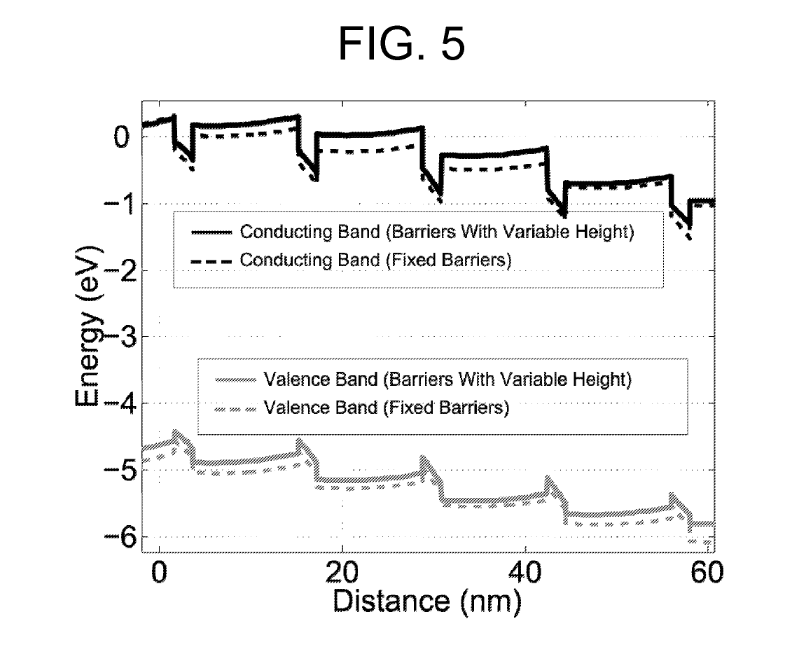

FIG. 5 shows an illustrative band gap diagram according to an embodiment. In particular, the band gap diagram corresponds to a portion of an active region 18 (FIG. 1) in which the molar fraction of a group III element varies from one barrier to another by changing the molar fraction of a group III element as shown in FIG. 3 (“varied barriers”). Furthermore, barriers having a substantially constant molar fraction across the entire active region (“fixed barriers”) are compared with the varied barriers. The barrier molar fraction for the fixed barriers was selected such that it is equal to the molar fraction of the first (outermost) barrier for the varied barriers. The varied barriers result in a quantum well depth for the first and last quantum wells in the active region to be reduced compared to the quantum wells in the central region, resulting in improved electron and hole injection in the active region including the varied barriers and towards the central region of the active region.

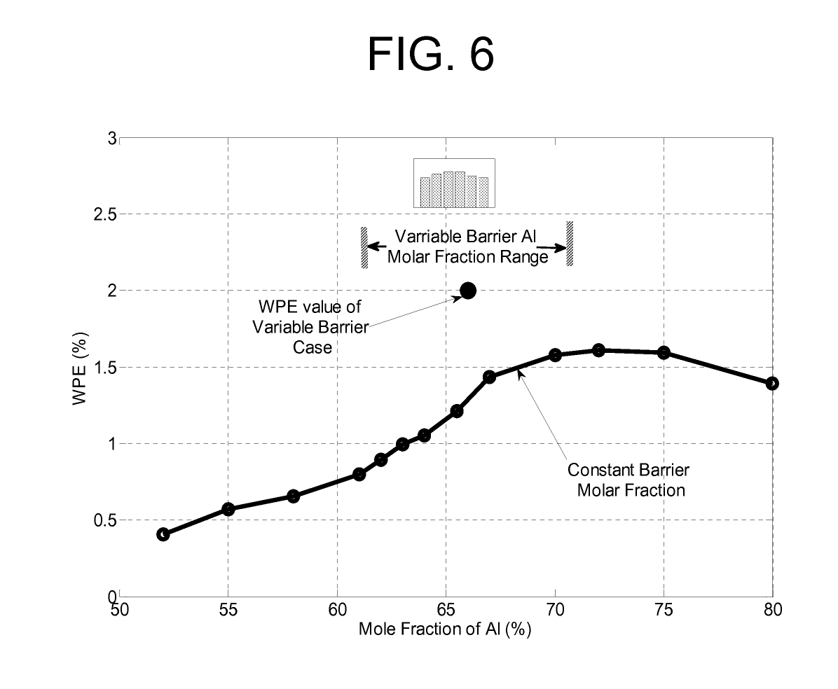

FIG. 6 shows an illustrative graph of wall plug efficiencies for various barrier structure configurations according to an embodiment. In particular, the wall plug efficiency (WPE) for several barrier structure configurations having differing molar fractions of Al that remain constant for each of the barriers across the active region are shown. The WPE values for various molar fractions of Al ranging between approximately 52% and 80% are shown, with a maximum WPE of approximately 1.6% obtained when the Al molar fraction is approximately 72%. However, a barrier structure configuration in which the molar fractions of Al increase from the outer barrier layers to the inner barrier layers of the active region (e.g., similar to that shown in FIG. 3) and range between approximately 62%-71% yielded a WPE of approximately 2%.

Returning to FIG. 1, it is understood that emitting device 10 can be manufactured using any solution. For example, a substrate 12 can be obtained, a buffer layer 14 can be formed (e.g., grown, deposited, and/or the like) thereon, and the n-type cladding layer 16 can be formed on the buffer layer 14. Furthermore, the active region 18, including the quantum wells and barriers as described herein, can be formed on the n-type cladding layer 16 using any solution. The p-type layer 20 can be formed on the active region 18 and the p-type cladding layer 22 can be formed on the p-type layer 20 using any solution. Metal layers 24, 28 and contacts 26, 30 also can be added to the emitting device 10, which can be attached to submount 36 via contact pads 32, 34. It is understood that the manufacture of emitting device 10 can include the deposition and removal of a temporary layer, such as mask layer, the patterning one or more layers, the formation of one or more additional layers not shown, and/or the like.

While shown and described herein as a method of designing and/or fabricating an emitting device, it is understood that aspects of the invention further provide various alternative embodiments. For example, in one embodiment, the invention provides a method of designing and/or fabricating a circuit that includes one or more of the emitting devices designed and fabricated as described herein.

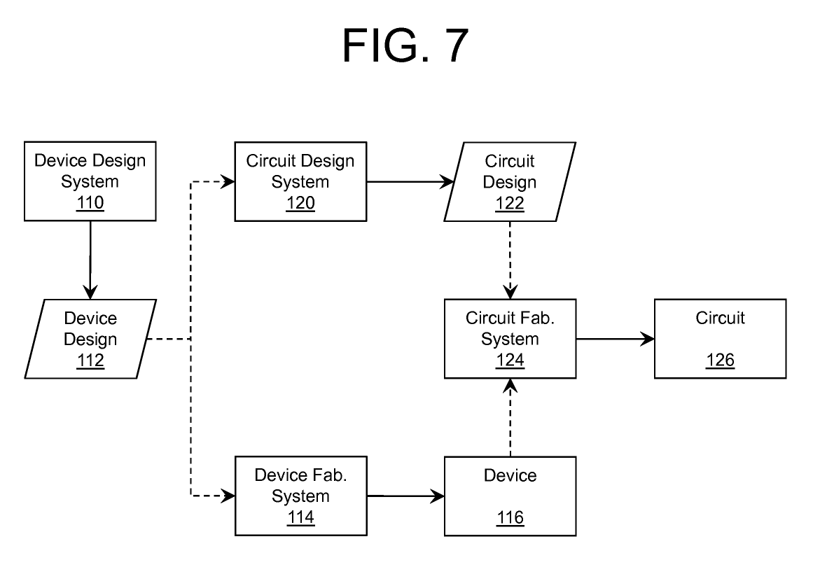

To this extent, FIG. 7 shows an illustrative flow diagram for fabricating a circuit 126 according to an embodiment. Initially, a user can utilize a device design system 110 to generate a device design 112 for an emitting device as described herein. The device design 112 can comprise program code, which can be used by a device fabrication system 114 to generate a set of physical devices 116 according to the features defined by the device design 112. Similarly, the device design 112 can be provided to a circuit design system 120 (e.g., as an available component for use in circuits), which a user can utilize to generate a circuit design 122 (e.g., by connecting one or more inputs and outputs to various devices included in a circuit). The circuit design 122 can comprise program code that includes a device designed as described herein. In any event, the circuit design 122 and/or one or more physical devices 116 can be provided to a circuit fabrication system 124, which can generate a physical circuit 126 according to the circuit design 122. The physical circuit 126 can include one or more devices 116 designed as described herein.

In another embodiment, the invention provides a device design system 110 for designing and/or a device fabrication system 114 for fabricating a semiconductor device 116 as described herein. In this case, the system 110, 114 can comprise a general purpose computing device, which is programmed to implement a method of designing and/or fabricating the semiconductor device 116 as described herein. Similarly, an embodiment of the invention provides a circuit design system 120 for designing and/or a circuit fabrication system 124 for fabricating a circuit 126 that includes at least one device 116 designed and/or fabricated as described herein. In this case, the system 120, 124 can comprise a general purpose computing device, which is programmed to implement a method of designing and/or fabricating the circuit 126 including at least one semiconductor device 116 as described herein.

In still another embodiment, the invention provides a computer program fixed in at least one computer-readable medium, which when executed, enables a computer system to implement a method of designing and/or fabricating a semiconductor device as described herein. For example, the computer program can enable the device design system 110 to generate the device design 112 as described herein. To this extent, the computer-readable medium includes program code, which implements some or all of a process described herein when executed by the computer system. It is understood that the term “computer-readable medium” comprises one or more of any type of tangible medium of expression, now known or later developed, from which a stored copy of the program code can be perceived, reproduced, or otherwise communicated by a computing device.

In another embodiment, the invention provides a method of providing a copy of program code, which implements some or all of a process described herein when executed by a computer system. In this case, a computer system can process a copy of the program code to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, the invention provides a method of generating a device design system 110 for designing and/or a device fabrication system 114 for fabricating a semiconductor device as described herein. In this case, a computer system can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; and/or the like.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. An emitting device comprising:
a group III-nitride based semiconductor structure including an active region, the active region comprising:
a plurality of quantum wells; and
a plurality of barriers alternating with the plurality of quantum wells, wherein at least one quantum well includes first and second adjacent barriers composed of a group III nitride material, wherein a molar fraction of a group III element in the group III nitride material differs for the first and second adjacent barriers by at least one percent.

2. The device of claim 1, wherein the first and second adjacent barriers have barrier heights differing by at least one percent.

3. The device of claim 1, wherein a molar fraction of another group III element in the group III nitride material differs for the first and second adjacent barriers by at least one percent.

4. The device of claim 1, wherein the device is configured to operate as one of: a light emitting diode or a laser diode.

5. The device of claim 1, wherein each of the plurality of barriers comprises a corresponding molar fraction of the group III element, and wherein the molar fractions of the plurality of barriers result in a barrier height of the corresponding barrier increasing in a direction toward a central portion of the active region.

6. The device of claim 1, wherein each of the plurality of barriers comprises a corresponding molar fraction of the group III element, and wherein the molar fractions of the plurality of barriers result in a barrier height of the corresponding barrier increasing in a direction from an n-type side of the active region to a p-type side of the active region.

7. The device of claim 1, wherein each of the plurality of barriers comprises a corresponding molar fraction of the group III element, and wherein the molar fractions of the plurality of barriers result in a barrier height of the corresponding barrier increasing in a direction from a p-type side of the active region to an n-type side of the active region.

8. The device of claim 1, wherein the group III element comprises one of: aluminum, indium, gallium, or boron.

9. The device of claim 1, wherein at least one of the plurality of barriers has a graded molar fraction of the group III element.

10. The device of claim 1, wherein the semiconductor structure further includes at least one heterointerface between a first layer and a second layer, wherein the first layer and the second layer have graded compositions adjacent to the heterointerface.

11. The device of claim 1, wherein the semiconductor structure further includes a p-type blocking layer having a graded composition.

12. The device of claim 1, the semiconductor structure further including:
a transparent p-type cladding layer having a short period superlattice structure; and
a transparent p-type contact layer having a short period superlattice structure.

13. The device of claim 12, further comprising:
an at least partially ultraviolet reflective n-type contact; and
an at least partially ultraviolet reflective p-type contact.

14. An emitting device comprising:
a group III-nitride based semiconductor structure including an active region, the active region comprising:
a plurality of quantum wells; and
a plurality of barriers alternating with the plurality of quantum wells, each of the plurality of barriers having a corresponding barrier height, wherein at least one quantum well includes two adjacent barriers having barrier heights differing by at least one percent.

15. The emitting device of claim 14, wherein a barrier of the two adjacent barriers having a lower barrier height is located closer to an outer portion of the active region.

16. The emitting device of claim 14, wherein the barrier heights of the plurality of barriers increase as the barriers are closer to a central portion of the active region.

17. The emitting device of claim 14, wherein the two adjacent barriers are composed of a group III nitride material, wherein a molar fraction of a group III element in the group III nitride material differs for the two adjacent barriers by at least one percent.

18. The emitting device of claim 17, wherein the group III element is aluminum.

19. A method of manufacturing an emitting device comprising:
forming a group III-nitride based semiconductor structure, the forming including:
forming an active region in the semiconductor structure, the active region comprising a plurality of quantum wells and a plurality of barriers alternating with the plurality of quantum wells, wherein the active region forming includes:
forming a first barrier adjacent to a quantum well, the first barrier having a first molar fraction of a group III element; and
forming a second barrier adjacent to the quantum well, the second barrier having a second molar fraction of the group III element, wherein the first and second molar fractions differ by at least one percent.

20. The method of claim 19, wherein the first and second barriers have barrier heights differing by at least one percent.
